(19) United States
(12) Patent Application Publication
(10) Pub. No.: US 2022/0059590 A1
(43) Pub. Date: Feb. 24, 2022

(54) SOLID-STATE IMAGING APPARATUS

(71) Applicants: TOWER PARTNERS SEMICONDUCTOR CO., LTD., Uozu City (JP); TOWER SEMICONDUCTOR LTD., Migdal Haemek (IL)

(72) Inventor: Hiroshi TANAKA, Kyoto (JP)

(73) Assignees: TOWER PARTNERS SEMICONDUCTOR CO., LTD., Uozu City (JP); TOWER SEMICONDUCTOR LTD., Migdal Haemek (IL)

(21) Appl. No.: 17/409,695

(22) Filed: Aug. 23, 2021

(30) Foreign Application Priority Data
Aug. 24, 2020 (JP) 2020-140644

(51) Int. Cl. H01L 27/146

(52) U.S. Cl. CPC H01L 27/14621; H01L 27/14623; H01L 27/1464; H01L 27/14685; H01L 27/14627; H01L 27/1463

(57) ABSTRACT

A solid-state imaging apparatus includes photoelectric conversion regions arranged close to a surface of a semiconductor substrate and a recessed portion provided above each photoelectric conversion region in the semiconductor substrate. Further, the solid-state imaging apparatus includes a light transmissive film embedded in the recessed portion. With this configuration, the performance of the solid-state imaging apparatus is improved, such as improvement of sensitivity and reduction in color mixture.

### CROSS-REFERENCE TO RELATED APPLICATIONS

This claims priority to Japanese Patent Application No. 2020-140644 filed to JPO on Aug. 24, 2020 under 35 U.S.C 119, the entire contents of which are incorporated herein by reference.

### BACKGROUND

As a solid-state imaging apparatus structure, a back side illumination (BSI) sensor has been known. In the BSI sensor, a photoelectric conversion portion of each pixel is arranged on a back side of a semiconductor substrate. In the case of a color imaging apparatus, a predetermined color filter is provided for each photoelectric conversion region. For avoiding a color mixture among the photoelectric conversion portions, a partition is provided in a region between the photoelectric conversion portions on the semiconductor substrate. Further, a lens configured to collect incident light is provided for each photoelectric conversion region. As a specific example, International Patent Publication No. 2017/073321 has been known.

### SUMMARY

The technique of the present disclosure is to improve the performance of a solid-state imaging apparatus, such as improvement of sensitivity and reduction in a color mixture.

The solid-state imaging apparatus of the present disclosure includes photoelectric conversion regions arranged close to a surface of a semiconductor substrate and a recessed portion provided above each photoelectric conversion region in the semiconductor substrate. Further, the solid-state imaging apparatus includes a light transmissive film embedded in the recessed portion.

According to the solid-state imaging apparatus of the present disclosure, the recessed portion is provided above each photoelectric conversion region so that performance improvement can be achieved, such as sensitivity improvement by a decrease in a height from the photoelectric conversion region to a lens and a color mixture reduction by the function of a region between the recessed portions as a partition.

### BRIEF DESCRIPTION OF THE DRAWINGS

FIG. 1 is a schematic view showing a section of an exemplary solid-state imaging apparatus of the present disclosure.

FIG. 2 is a schematic view showing a section of a solid-state imaging apparatus of a comparative example.

FIG. 3 is a schematic view showing a section of a main portion of a solid-state imaging apparatus of a variation of the present disclosure.

FIG. 4 is a schematic view showing a section of a main portion of a solid-state imaging apparatus of another variation of the present disclosure.

FIG. 5 is a schematic view showing a section of a main portion of a solid-state imaging apparatus of still another variation of the present disclosure.

FIG. 6 is a schematic view showing a section of a main portion of a solid-state imaging apparatus of still another variation of the present disclosure.

FIG. 7 is a view for describing the step of manufacturing the solid-state imaging apparatus of the present disclosure.

FIG. 8 is a view for describing the step of manufacturing the solid-state imaging apparatus of the present disclosure after FIG. 7.

FIG. 9 is a view for describing the step of manufacturing the solid-state imaging apparatus of the present disclosure after FIG. 8.

FIG. 10 is a view for describing the step of manufacturing the solid-state imaging apparatus of the present disclosure after FIG. 9.

FIG. 11 is a view for describing the step of manufacturing the solid-state imaging apparatus of the present disclosure after FIG. 10.

### DETAILED DESCRIPTION

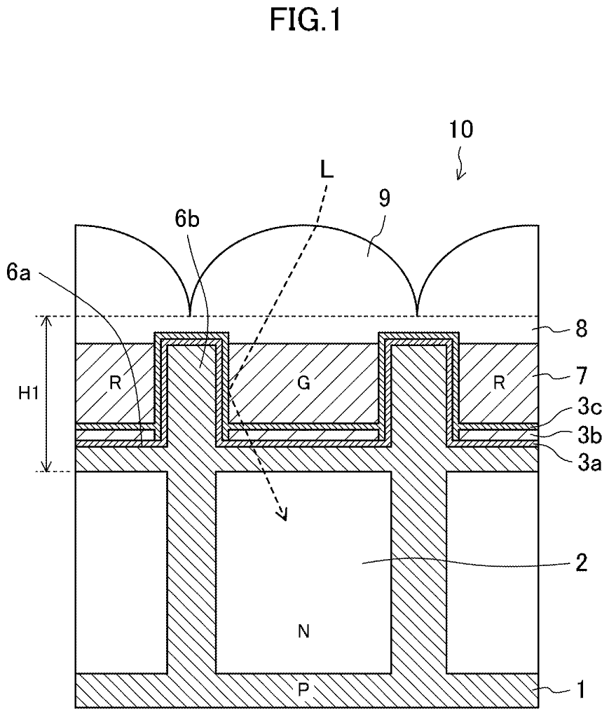

Hereinafter, an embodiment of the present disclosure will be described. FIG. 1 is a schematic sectional view for describing a configuration of a main portion of an exemplary solid-state imaging apparatus 10 of the present embodiment.

The solid-state imaging apparatus 10 shown in FIG. 1 is formed using a p-type semiconductor substrate 1. Photoelectric conversion regions 2 are provided as N-type impurity regions in the semiconductor substrate 1.

The solid-state imaging apparatus 10 is of a back side illumination type. A transistor and a wiring for reading a photoelectrically-converted charge are arranged on the side (the lower side in FIG. 1) of the semiconductor substrate 1 opposite to a sensor side (the upper side in FIG. 1) including the photoelectric conversion regions 2, and a logic-side semiconductor substrate is arranged further on the lower side (any of these components are not shown). Incident light L enters from a back side, and a logic side opposite thereto is a front side. In the present disclosure, a “back side” means a solid-state imaging apparatus side from which light enters.

The photoelectric conversion regions 2 are provided close to the surface of the semiconductor substrate 1. FIG. 1 shows the entirety of a single photoelectric conversion region 2, and on both sides thereof, shows only part of photoelectric conversion regions 2. A recessed portion 6a in such a shape that the semiconductor substrate 1 is partially removed from the surface thereof is provided above each photoelectric conversion region 2. The semiconductor substrate 1 remains to form a partition portion 6b between the recessed portions 6a. The semiconductor substrate 1 is of the P-type, and therefore, a p-type impurity is injected into the recessed portion 6a of the semiconductor substrate 1.

A color filter 7 as a light transmissive film is embedded in the recessed portion 6a. As the color filter 7, any of color filters allowing transmission of light with wavelength bands of red, blue, and green may be provided in each recessed portion 6a, for example. In FIG. 1, the color filter corresponding to the wavelength band of green (indicated by G) is provided in the recessed portion 6a at the center, and the color filters corresponding to the wavelength band of red (indicated by R) are provided in the recessed portions 6a above the photoelectric conversion regions 2 on both sides. Moreover, at a location not shown in FIG. 1, the color filter corresponding to the wavelength band of blue is provided.

An insulating film 3a and an insulating film 3c made of, e.g., SiO₂ are, as films with light refractive indices lower than that of the color filter 7, provided between the semiconductor substrate 1 and the color filter 7 on bottom and side surfaces of the recessed portion 6a. The insulating film 3a and the insulating film 3c also cover the partition portion 6b between the recessed portions 6a. Since the light refractive indices of the insulating film 3a and the insulating film 3c are lower than the refractive index of the color filter 7, the incident light L is reflected on the side surface of the recessed portion 6a and changes one's path toward the photoelectric conversion region 2. As a result, a color mixture is prevented, and the light entering the photoelectric conversion region 2 increases. Thus, the sensitivity of the imaging apparatus is improved.

Moreover, an anti-reflective film 3b such as a SiN film is provided between the semiconductor substrate 1 and the color filter 7 on the bottom surface of the recessed portion 6a. As shown in FIG. 1, the anti-reflective film 3b may be provided between the insulating film 3a and the insulating film 3c. With this configuration, reflection of the incident light on the bottom surface of the recessed portion 6a is reduced, and the light entering the photoelectric conversion region 2 increases. Thus, the sensitivity of the imaging apparatus is improved.

A planarization film 8 made of a transparent material, such as an acrylic film, is provided to cover the color filters 7 and the partition portions 6b. A lens 9 is, on the planarization film 8, provided corresponding to each photoelectric conversion region 2. With the lens 9, the incident light is condensed to each photoelectric conversion region 2.

According to the solid-state imaging apparatus 10 having the above-described configuration, a height H1 from an upper surface of the photoelectric conversion region 2 to a lower surface of the lens 9 can be decreased. As a result, the efficiency of light condensation to the photoelectric conversion region 2 is improved, and the sensitivity is improved accordingly. The partition portions 6b can be utilized to suppress the light having entered the lens 9 provided above each photoelectric conversion region 2 from entering the adjacent photoelectric conversion regions 2. With this configuration, the color mixture is reduced.

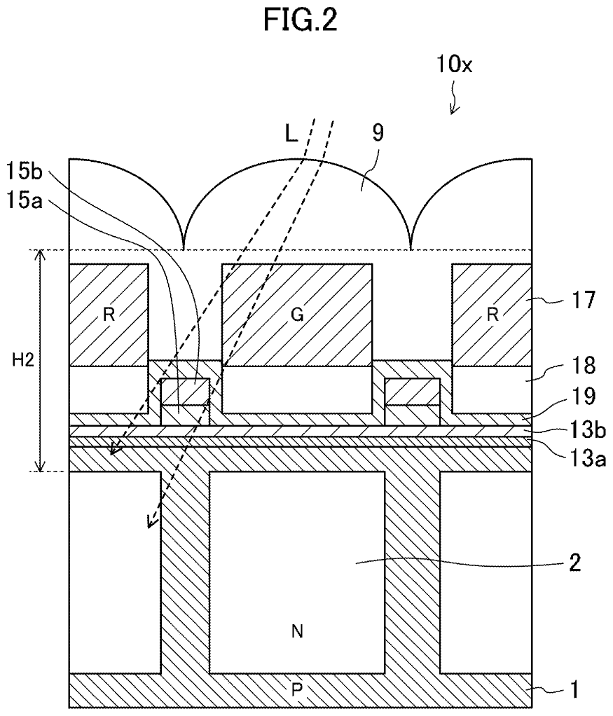

This will be further described with reference to FIG. 2. FIG. 2 is a view showing a solid-state imaging apparatus 10x having a known structure in which color filters are provided in a planarization film.

In the solid-state imaging apparatus 10x of FIG. 2, photoelectric conversion regions 2 are provided close to a surface of a semiconductor substrate 1. The thickness of a portion of the semiconductor substrate 1 above the photoelectric conversion region 2 is in the same range as that in the case of the solid-state imaging apparatus 10 of FIG. 1. However, it is not configured such that the recessed portions 6a are provided with the partition portions 6b, but it is configured such that a corresponding portion is flat.

An insulating film 13a and an anti-reflective film 13b are provided in this order to cover the semiconductor substrate 1. In a region between the photoelectric conversion regions 2, an insulating film 15a is provided on the anti-reflective film 13b, and a light shielding film 15b is further provided on the insulating film 15a. A protective film 19 is provided to cover the insulating film 15a, the light shielding film 15b, and the anti-reflective film 13b, and a planarization film 18 covering the protective film 19 is further provided. A color filter 17 is provided in a region above each photoelectric conversion region 2 in the planarization film 18. Lenses 9 are provided on the planarization film 18.

In the solid-state imaging apparatus 10x, it is essential to provide the light shielding film 15b for reducing a color mixture in nature.

Moreover, in a case where a lower surface of the color filter 17 is positioned higher than an upper surface of the light shielding film 15b as in FIG. 2, it is difficult to decrease a height H2 from an upper surface of the photoelectric conversion region 2 to a lower surface of the lens 9. Unlike FIG. 2, even with a configuration in which the color filter 17 is arranged between the insulating film 15a and the light shielding film 15b, the insulating film 15a and the light shielding film 15b generally have heights less than that of the partition portion 6b in the present disclosure. For this reason, the effect of reducing the color mixture is less than that in the case of providing the partition portions 6b.

On the other hand, because of the configuration in which the partition portions 6b remain in the semiconductor substrate 1 to provide the recessed portions 6a in the case of the solid-state imaging apparatus 10 of FIG. 1, the height H1 can be decreased and the sensitivity can be improved while the color mixture is reduced.

Microfabrication of the photoelectric conversion region 2 etc. has progressed with an increase in the number of pixels in the imaging apparatus. Manufacturing becomes more difficult as the structure is microfabricated. However, microfabrication of a photoresist pattern is not necessary for microfabrication of the recessed portion 6a and the partition portion 6b, and such microfabrication can be relatively easily achieved. For example, anisotropic dry etching is first performed to form the recessed portions such that the semiconductor substrate is engraved mainly in a depth direction. Accordingly, a portion to be the partition portion remains between the recessed portions in the semiconductor substrate. Subsequently, by isotropic dry etching, etching also progresses in a direction in which the recessed portion is expanded, and therefore, the width of the partition portion can be decreased.

On the other hand, in the case of the structure shown in FIG. 2, microfabrication of a photomask is necessary, and for this reason, is not easy.

Further, a case where the light enters the partition portion 6b and a charge is generated due to photoelectric conversion in the partition portion 6b will be assumed. Such a charge leads to noise. However, the partition portion 6b is formed of the p-type semiconductor substrate 1, and therefore, such a charge is recombined with a hole and is neutralized. Thus, e.g., degradation of an image due to the noise is reduced.

Note that the example of using the p-type semiconductor substrate 1 has been described above, but an n-type semiconductor substrate can be also used. In this case, for, e.g., a portion of the n-type semiconductor substrate above the photoelectric conversion region 2 or an upper portion in a region between the partition portions 6b or between the photoelectric conversion regions 2, ion implantation is performed using, e.g., a p-type impurity (boron etc.), and in this manner, a p-type impurity region is formed. Alternatively, a two-layer substrate configured such that an n-type layer is epitaxially grown on a p-type layer can be used.

(First Variation)

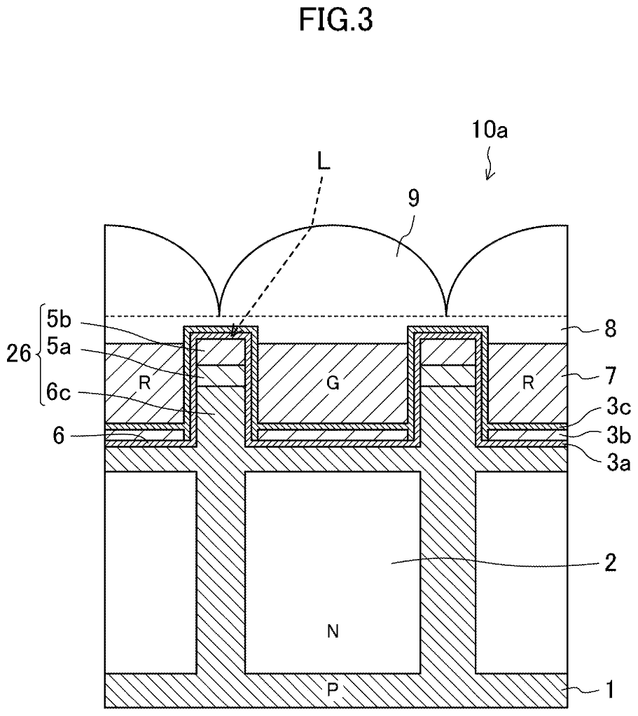

Next, FIG. 3 is a view showing a solid-state imaging apparatus 10a of a first variation of the embodiment. In FIG. 3, the same reference numerals are used to represent components similar to those of the solid-state imaging apparatus 10 of FIG. 1, and differences will be mainly described below.

In the solid-state imaging apparatus 10a of FIG. 3, a light shielding film 5b is, through an insulating film 5a, provided on a partition portion 6c as a remaining portion of the semiconductor substrate 1 in a region between the photoelectric conversion regions 2. The height of the partition portion 6c is less than that of the partition portion 6b of FIG. 1, and the height of a partition structure 26 including the partition portion 6b, the insulating film 5a, and the light shielding film 5b is in the same range as that of the partition portion 6b of FIG. 1. With the partition structure 26, the recessed portion 6a is formed above the photoelectric conversion region 2, and the color filter 7 is provided in the recessed portion 6a.

As described above, the partition structure 26 with the light shielding film 5b is provided so that entrance of light having passed through the lens 9 above a particular photoelectric conversion region 2, such as the incident light L indicated by a dashed arrow, into adjacent photoelectric conversion regions 2 can be prevented and the color mixture can be reduced.

Moreover, flare can be also reduced by the light shielding film 5b. The flare is a phenomenon that in the case of photographing with a high-intensity light source, incident light is reflected on a lens surface and enters a pixel again. The light having entered again turns into a false signal, leading to image degradation. The light shielding film 5b can also reduce such light reentrance, and as a result, can reduce the flare.

(Second Variation)

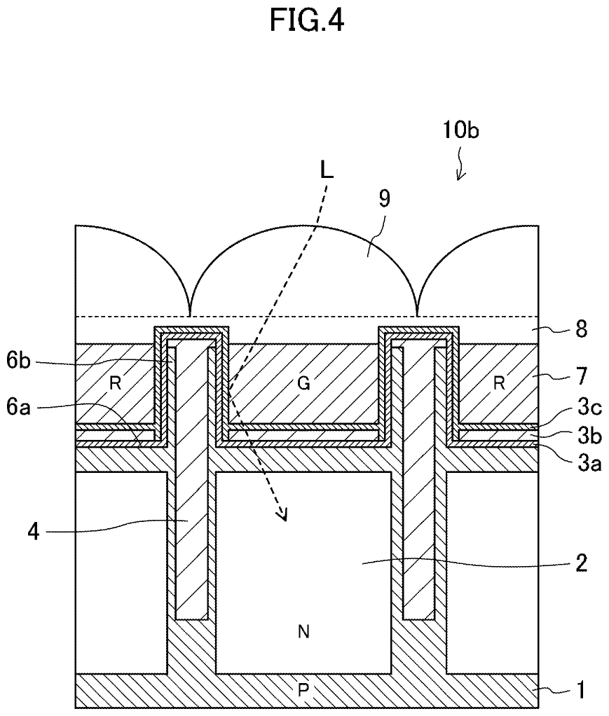

Next, FIG. 4 is a view showing a solid-state imaging apparatus 10b of a second variation of the embodiment. In FIG. 4, the same reference numerals are used to represent the components described so far, and differences will be mainly described below.

In the solid-state imaging apparatus 10b, an element separation layer 4 (deep trench isolation: DTI) is provided in the partition portion 6b. The element separation layer 4 is formed in such a manner that a groove is formed from the upper side (the side of the semiconductor substrate 1 on which the recessed portion 6a is formed) in FIG. 4 and an insulating film is embedded in such a groove, and is formed to reach a portion deeper than the upper surface of the photoelectric conversion region 2. Thus, the element separation layer 4 has a portion interposed between the photoelectric conversion regions 2.

The element separation layer 4 is provided in the partition portion 6b so that charge leakage to between regions corresponding to adjacent photoelectric conversion regions 2 can be reduced. Moreover, the element separation layer 4 can be made of a light shielding material to further reduce light leakage.

(Third Variation)

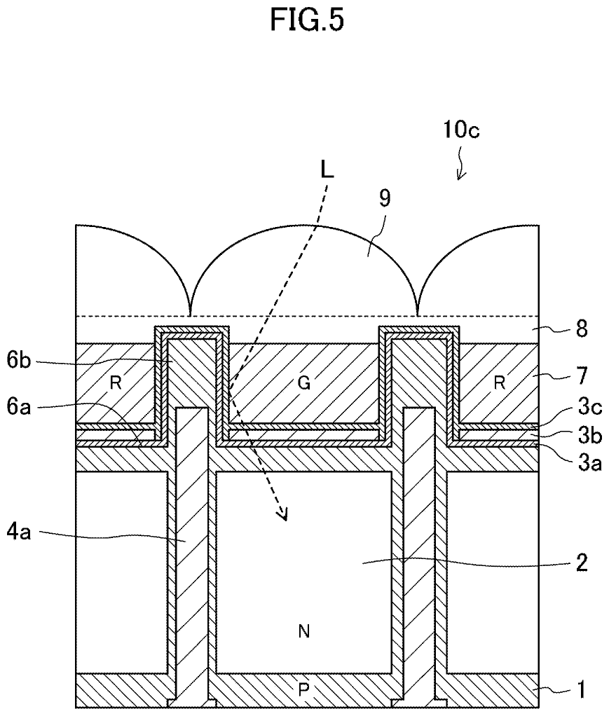

Next, FIG. 5 is a view showing a solid-state imaging apparatus 10c of a third variation of the embodiment. In FIG. 5, the same reference numerals are used to represent the components describe so far, and differences will be mainly described below.

In the solid-state imaging apparatus 10c, an element separation layer 4a is provided in the partition portion 6b. Note that contrary to the solid-state imaging apparatus 10b of FIG. 4, the element separation layer 4a is formed from the lower side (the side of the semiconductor substrate 1 opposite to the recessed portion 6a) in FIG. 5.

In the example of FIG. 5, the element separation layer 4a extends to above the bottom surface of the recessed portion 6a. Thus, in an area from a lower surface to the upper surface of the photoelectric conversion region 2, the element separation layer 4a is arranged between the photoelectric conversion regions 2.

Even with such an element separation layer 4a, charge leakage to between regions corresponding to adjacent photoelectric conversion regions 2 can be reduced. Moreover, the element separation layer 4a can be also made of a light shielding material to further reduce light leakage.

(Fourth Variation)

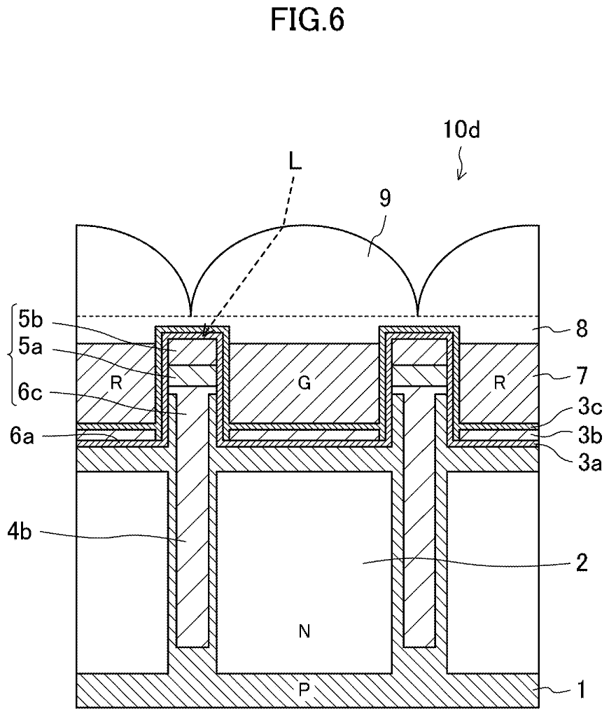

Next, FIG. 6 is a view showing a solid-state imaging apparatus 10d of a fourth variation of the embodiment. In FIG. 6, the same reference numerals are used to represent the components describe so far, and differences will be mainly described below.

In the solid-state imaging apparatus 10d, an element separation layer 4b is formed in the partition portion 6c, and the light shielding film 5b is formed on the partition portion 6c through the insulating film 5a to form the partition structure 26. With this configuration, both of the advantageous effect (similar to that of the solid-state imaging apparatus 10a of FIG. 3) of formation of the light shielding film 5b on the partition portion 6c and the advantageous effect (similar to that of the solid-state imaging apparatus 10b of FIG. 4) of formation of the element separation layer 4b in the partition portion 6c can be achieved.

Method for Manufacturing Solid-State Imaging Apparatus

Next, the method for manufacturing the solid-state imaging apparatus of the present disclosure will be described. Particularly, the manufacturing method will be described regarding the back-side structure of the solid-state imaging apparatus including the recessed portions 6a, the partition portions 6c (the partition structures 26), the color filters 7, etc. Moreover, the configuration in which the light shielding film 5b is provided on the partition portion 6c as shown in FIG. 3 will be taken as an example.

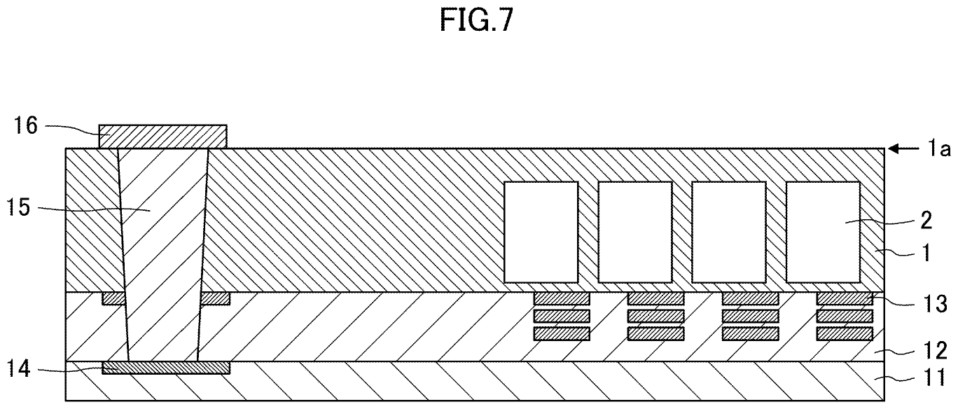

FIG. 7 shows the solid-state imaging apparatus in the middle of manufacturing. Specifically, the sensor-side semiconductor substrate 1 provided with the photoelectric conversion regions 2 as n-type impurity layers and a logic-side semiconductor substrate 11 in which, e.g., a circuit (not shown) for image signal processing is formed are joined to each other through a wiring layer 12 including lines 13. The figure does not necessarily show a precise scale, and the logic-side semiconductor substrate 11 is shown thinner, for example.

For forming such a structure, the photoelectric conversion regions 2 is formed in the semiconductor substrate 1, and the wiring layer 12 including the lines 13 is formed on the semiconductor substrate 1, for example. Thereafter, the logic-side semiconductor substrate 11 formed with the circuit is joined to the wiring layer 12. Further, the sensor-side semiconductor substrate 1 is thinned from the back side.

A through-silicon via 15 (TSV) penetrating the semiconductor substrate 1 and the wiring layer 12 is formed, and is connected to a pad 16 made of aluminum on the back side of the semiconductor substrate 1 and is connected to a line 14 on a logic-side semiconductor substrate 11 side.

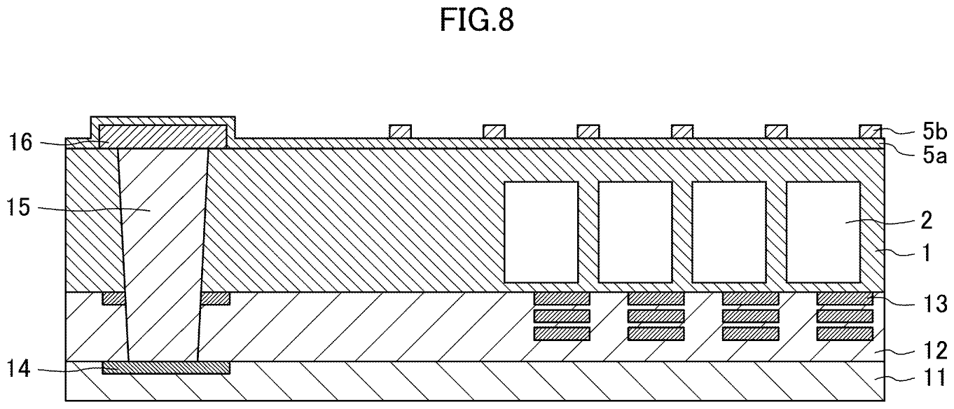

Next, the step of FIG. 8 will be described. First, the insulating film 5a made of, e.g., a silicon oxide film is formed to cover a back side surface la of the semiconductor substrate 1 and the pad 16. Subsequently, the light shielding film 5b made of, e.g., tungsten is formed on the insulating film 5a. For such formation, a tungsten layer may be deposited on the insulating film 5a by sputtering, and thereafter, a mask may be formed on the tungsten layer and a portion other than a necessary portion may be removed by etching, for example. The light shielding film 5b is formed at least above a region sandwiched by the photoelectric conversion regions 2.

Note that the light shielding film 5b is also provided at a portion where no photoelectric conversion region 2 is formed (e.g., the light shielding film 5b on the leftmost side in FIG. 8). This portion is a dummy for improving a pattern formation accuracy. That is, in some cases, the formation accuracy is degraded at a non-continuous pattern portion upon pattern formation. For this reason, a similar pattern is also provided outside a region above a pixel, and in this manner, the accuracy at a necessary portion of the light shielding film 5b is obtained.

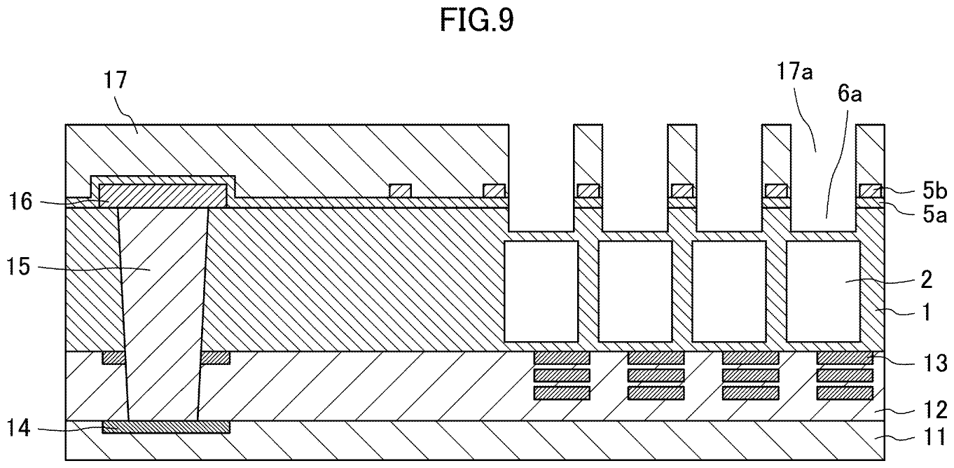

Next, the step of FIG. 9 will be described. First, a resist 17 is formed to cover the insulating film 5a and the light shielding film 5b. Further, by, e.g., photolithography, a predetermined pattern with openings 17a is formed in regions where the recessed portions 6a are to be formed.

Subsequently, by, e.g., etching, the insulating film 5a exposed through the openings 17a is removed, and part of the semiconductor substrate 1 is removed. In this manner, the recessed portion 6a is formed above each photoelectric conversion region 2. Thereafter, the resist 17 is removed.

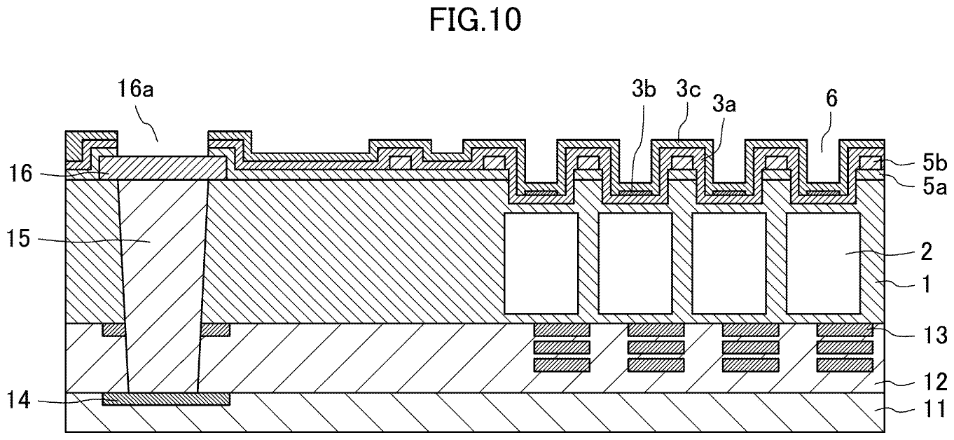

Next, the step of FIG. 10 will be described. First, the insulating film 3c is formed to cover the bottom and side surfaces of each recessed portion 6a, the insulating film 5a, the light shielding film 5b, the pad 16, etc. Next, the anti-reflective film 3b is formed on the insulating film 3a on the bottom surface of the recessed portion 6a. This film is, for example, formed in such a manner that after the film has been formed to cover the insulating film 3c, a photo resist with a pattern corresponding to the anti-reflective film 3b to be formed is formed and an unnecessary portion is removed by etching. Further, the insulating film 3c is formed to cover the anti-reflective film 3b and the insulating film 3a. In this manner, the anti-reflective film 3b sandwiched by the insulating film 3a and the insulating film 3c is formed on the bottom surface of the recessed portion 6a. Note that each film may be formed by, e.g., a CVD method or a PVD method.

Thereafter, the insulating film 5a, the insulating film 3a, and the insulating film 3c are removed from the pad 16 by, e.g., etching, and in this manner, a pad opening 16a is formed.

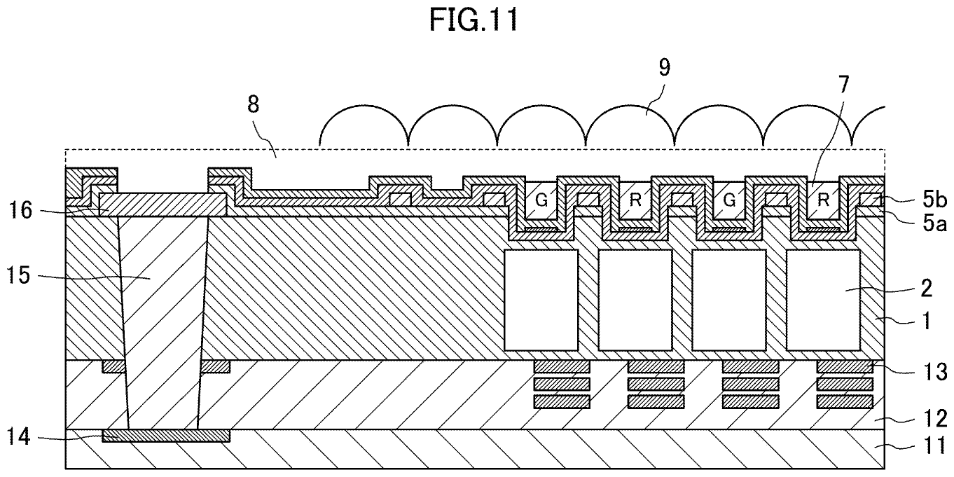

Next, the step of FIG. 11 will be described. At this step, the color filter 7 is formed in the recessed portion 6a above each photoelectric conversion region 2. FIG. 11 shows the color filters 7 (indicated by G and R in this order) corresponding to the wavelength bands of green and red, and the color filters corresponding to the wavelength band of blue are also further formed.

Note that the color filter 7 is formed by, e.g., a photolithography technique. For example, a filter material of R is applied, exposed to light, and developed such that the filters of R are formed only for desired pixels. Thereafter, the filters of G and B are similarly formed.

Thereafter, the planarization film 8 made of the transparent material is formed to cover the color filters 7, the insulating film 3c, etc. Further, the lens 9 is, on the planarization film 18, formed corresponding to each photoelectric conversion region 2.

By the above-described steps, the solid-state imaging apparatus is manufactured. Note that this method is one example and the manufacturing method is not particularly limited. Moreover, the material of each component etc. are not limited to the above-described contents, either.

The solid-state imaging apparatus configured to acquire a color image has been described above. Thus, the color filter 7 allowing transmission of light corresponding to any of some different wavelength bands is formed in each recessed portion 6a. However, the present invention is also applicable to a solid-state imaging apparatus configured to acquire a black-and-white image. In this case, it may only be required that at least a transparent film allowing transmission of visible light is formed in each recessed portion 6a.

According to the technique of the present disclosure, reduction in the color mixture and performance improvement such as sensitivity improvement are achieved. Thus, such a technique is useful for the solid-state imaging apparatus.

What is claimed is:

1. A solid-state imaging apparatus comprising:
photoelectric conversion regions arranged close to a surface of a semiconductor substrate;
a recessed portion provided above each photoelectric conversion region in the semiconductor substrate; and
a light transmissive film embedded in the recessed portion.

2. The solid-state imaging apparatus according to claim 1, further comprising:
a low-refractive-index film provided between the semiconductor substrate and the light transmissive film on bottom and side surfaces of the recessed portion and having a refractive index lower than that of the light transmissive film; and
an anti-reflective film provided between the semiconductor substrate and the light transmissive film on the bottom surface of the recessed portion.

3. The solid-state imaging apparatus according to claim 1, further comprising:
a light-shielding film on a partition portion as a portion of the semiconductor substrate remaining between the recessed portions.

4. The solid-state imaging apparatus according to claim 1, wherein
a p-type impurity is injected into the recessed portion of the semiconductor substrate.

5. The solid-state imaging apparatus according to claim 1, wherein
an element separation layer is provided in a partition portion as a portion of the semiconductor substrate remaining between the recessed portions, and
the element separation layer is formed from a recessed portion side of the semiconductor substrate.

6. The solid-state imaging apparatus according to claim 1, wherein
an element separation layer is provided in a partition portion as a portion of the semiconductor substrate remaining between the recessed portions, and
the element separation layer is formed from a side of the semiconductor substrate opposite to the recessed portion.

7. The solid-state imaging apparatus according to claim 1, wherein
the light transmissive film includes color filters allowing transmission of light with different wavelength bands.

8. The solid-state imaging apparatus according to claim 1, wherein
the light transmissive film is a transparent film allowing at least transmission of visible light.
